(19) United States
(12) Patent Application Publication
(10) Pub. No.: US 2007/0006800 A1
(43) Pub. Date: Jan. 11, 2007

(54) METHODS OF SELECTIVELY FORMING AN EPITAXIAL SEMICONDUCTOR LAYER USING ULTRA HIGH VACUUM CHEMICAL VAPOR DEPOSITION TECHNIQUE AND BATCH-TYPE ULTRA HIGH VACUUM CHEMICAL VAPOR DEPOSITION APPARATUS USED THEREIN

(76) Inventors: Deok-Hyung LEE, Seoul (KR); Min-Gu KANG, Seoul (KR); Yu-Gyun SHIN, Gyeonggi-do (KR); Jong-Wook LEE, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/428,513

(22) Filed: Jul. 3, 2006

(30) Foreign Application Priority Data
Jul. 8, 2005 (KR) 2005-0061920

(51) Int. Cl. C30B 23/00; C30B 25/00; C30B 28/12; C30B 28/14

(52) U.S. Cl. 117/95

(57) ABSTRACT

Provided are methods of selectively forming an epitaxial semiconductor layer using an ultra high vacuum chemical vapor deposition (UHVCVD) technique. One embodiment is directed to a method that includes loading a substrate having an insulating layer pattern into a reaction furnace. The reaction furnace is evacuated, and the substrate in the reaction furnace is heated to a temperature of about 550 to about 700° C. A semiconductor source gas is injected into the reaction furnace for a first duration to selectively form an epitaxial semiconductor layer on a region of the heated substrate. The semiconductor source gas remaining in the reaction furnace is then purged for a second duration. A selective etching gas is injected into the reaction furnace for a third duration to selectively remove semiconductor atoms adsorbed on surfaces of the insulating layer pattern. The selective etching gas remaining in the reaction furnace is then purged for a fourth duration. A carrier gas may be injected into the reaction furnace during at least the second to fourth durations.

### CROSS-REFERENCE TO RELATED APPLICATION

This U.S. non-provisional patent application claims priority under 35 U.S.C. §119 from Korean Patent Application 2005-0061920 filed on Jul. 8, 2005, the entire contents of which are hereby incorporated by reference.

### BACKGROUND

1. Field of the Invention

The present invention relates to selective epitaxial growth (SEG) processes employed in the fabrication of a semiconductor device and chemical vapor deposition (CVD) apparatus used therein and, more particularly, to methods of selectively forming an epitaxial semiconductor layer using a ultra high vacuum chemical vapor deposition (UHVCVD) technique and a batch-type ultra high vacuum chemical vapor deposition (UHVCVD) apparatus used therein.

2. Description of Related Art

Semiconductor devices are manufactured using various unit processes. Among these unit processes, a selective epitaxial growth (SEG) process has been widely used in the fabrication of highly integrated semiconductor devices. The SEG process is a process of selectively forming a semiconductor layer on a predetermined region of a semiconductor substrate such as a silicon substrate. Such a SEG process is widely used to form contact plugs of a semiconductor device, raised source/drain regions of a MOS transistor, or body layers of single crystal thin film transistors (TFTs).

A method of forming raised source/drain regions using the SEG process is disclosed in U.S. Pat. No. 6,429,084 B1 to Park, et al., entitled “MOS Transistors with Raised Sources and Drains.” According to Park, et al., the SEG process is performed at a high temperature of 750 to 850° C.

A conventional SEG process has been performed using a low pressure chemical vapor deposition (LPCVD) technique. Such a LPCVD SEG process is performed at a high temperature of 750 to 850° C. as disclosed in U.S. Pat. No. 6,429,084 B1. Therefore, when the LPCVD SEG process is used in the fabrication of highly integrated semiconductor devices, it may be difficult to suppress a short channel effect of the MOS transistors.

Furthermore, the LPCVD SEG process is generally performed under a pressure of 10 to 20 Torr. In this case, atoms thermally decomposed from a semiconductor source gas and a selective etching gas, which are used in the LPCVD SEG process, have a short mean free path of several millimeters (mm) or less under the pressure of 10 to 20 Torr. As a result, an epitaxial growth rate and a selective etching rate may be non-uniform throughout the semiconductor substrates loaded in a reaction furnace or throughout the surface of each of the semiconductor substrates. Therefore, the semiconductor source gas and the selective etching gas should be supplied together with a carrier gas such as a hydrogen gas during the LPCVD SEG process.

Although the LPCVD SEG process is performed using a single wafer type chamber, the carrier gas (e.g., a hydrogen gas) is injected into the single wafer type chamber at a high flow rate of at least 20,000 sccm (standard cubic centimeter per minute). In this case, hydrogen atoms decomposed from the hydrogen gas may be bonded to dangling bonds at the surface of the semiconductor substrate, thereby degrading the epitaxial growth rate and/or the uniformity thereof.

Recently, a single wafer type UHVCVD epitaxial growth process has been proposed to improve disadvantages of the LPCVD SEG process. However, the single wafer type UHVCVD epitaxial growth process is performed at a low process temperature, thereby exhibiting low epitaxial growth rates. Hence, the single wafer type UHVCVD epitaxial growth process may have a disadvantage of low throughput.

### SUMMARY

Some embodiments of the present the invention are directed to UHVCVD SEG processes. In one embodiment, the processes include forming an insulating layer pattern on a semiconductor substrate. The insulating layer pattern is formed to expose at least one region of the semiconductor substrate. The substrate having the insulating layer pattern is loaded into a reaction chamber such as a reaction furnace. The reaction chamber is evacuated, and the substrate in the reaction furnace is heated to a temperature of about 550 to about 700° C. during evacuation of the reaction furnace. A semiconductor source gas is injected into the reaction furnace for a first duration to selectively form an epitaxial semiconductor layer on the region of the heated substrate. The semiconductor source gas remaining in the reaction furnace is then purged for a second duration. A selective etching gas is then injected into the reaction furnace for a third duration to selectively remove semiconductor atoms adsorbed on surfaces of the insulating layer pattern. The selective etching gas remaining in the reaction furnace is purged for a fourth duration. A carrier gas may also be injected into the reaction furnace during at least the second to fourth durations.

### BRIEF DESCRIPTION OF THE DRAWINGS

The foregoing and other objects, features and advantages of the invention will be apparent from the detailed description of exemplary embodiments of the present invention, as illustrated in the accompanying drawings.

FIG. 1 is a schematic view of a batch-type UHVCVD apparatus in accordance with an embodiment of the present invention.

FIGS. 2A and 2B are process flowcharts illustrating a method of forming a selective epitaxial semiconductor layer using the apparatus illustrated in FIG. 1.

FIG. 3 is a timing diagram illustrating an SEG process in accordance with an embodiment of the present invention.

FIGS. 4A to 4D are cross-sectional views illustrating reaction mechanisms during an SEG process in accordance with an embodiment of the present invention.

FIG. 5 is a graph showing the relationship between an etch uniformity and a carrier gas used in an SEG process in accordance with embodiments of the present invention.

FIG. 6 is a graph showing the relationship between wafer to wafer growth uniformity and process temperature of epitaxial silicon layers formed in accordance with embodiments of the present invention.

FIG. 7 is a graph showing the relationship between growth uniformity within a wafer and the position of the wafers having epitaxial silicon layers formed in accordance with embodiments of the present invention.

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions may be exaggerated for clarity, and are thus not necessarily to scale; rather emphasis has been placed upon illustrating the principles of the invention. Like reference numerals designate like elements throughout the specification.

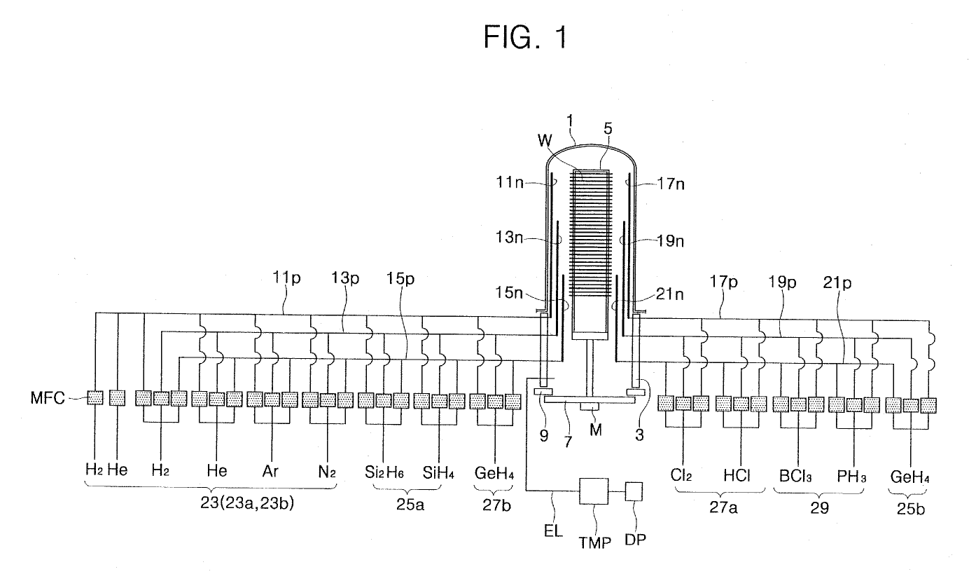

FIG. 1 is a schematic view of a batch-type UHVCVD apparatus used in SEG processes in accordance with an embodiment of the present invention.

Referring to FIG. 1, the batch-type UHVCVD apparatus includes a reaction chamber, e.g., reaction furnace 1. The reaction furnace 1 may be, for example, a vertical furnace. The vertical furnace 1 provides a space for performing an SEG process. A flange 3 may be attached to a lower portion of the vertical furnace 1. The flange 3 may have a cylindrical shape. A boat 5 may be loaded into the vertical furnace 1 through a space surrounded by the flange 3. The boat 5 may have a plurality of slots, and a plurality of semiconductor substrates, i.e., semiconductor wafers W may be inserted into the slots. The boat 5 may generally be divided into a plurality of batch zones. For example, the boat 5 may be divided into a top zone, a center zone and a bottom zone. Each of the batch zones may include slots in which about 10 to about 70 semiconductor wafers may be inserted.

A boat supporting plate 7 may be attached to a lower portion of the boat 5, and a motor M may be installed at a lower portion of the boat supporting plate 7. The motor M can rotate the boat 5 loaded into the vertical furnace 1 during an epitaxial growth process.

If the boat 5 is loaded into the vertical furnace 1, the boat supporting plate 7 may preferably be in contact with a sealing member 9, which may be attached to a lower portion of the flange 3 to isolate the space in the vertical furnace 1 from the external environment and air.

A plurality of gas nozzles 11n-21n are installed in the vertical furnace 1. Process gases, carrier gases, and/or purge gases are supplied through these gas nozzles toward the semiconductor wafers W in the boat 5 loaded into the vertical furnace 1. The plurality of gas nozzles may include a first group of gas nozzles and a second group of gas nozzles.

The first group of gas nozzles may include at least two gas nozzles having different heights from each other, and the second group of gas nozzles may also include at least two gas nozzles having different heights from each other. However, for the ease and convenience of explanation, it will be assumed that the first group of gas nozzles include first to third gas nozzles 11n, 13n, and 15n having different heights and the second group of nozzles include fourth to sixth gas nozzles 17n, 19,n and 21n having different heights. The first to third gas nozzles 11n, 13n, and 15n may be installed to face the fourth to sixth gas nozzles 17n, 19n, and 21n, respectively.

In the present embodiment, the first gas nozzle 11n may be located at a level higher than that of the second gas nozzle 13n, and the second gas nozzle 13n may be located at a level higher than that of the third gas nozzle 15n. Similarly, the fourth gas nozzle 17n may be located at a level higher than that of the fifth gas nozzle 19n, and the fifth gas nozzle 19n may be located at a level higher than that of the sixth gas nozzle 21n. In addition, the first to sixth gas nozzles 11n, 13n, 15n, 17n, 19n, and 21n may be disposed to have levels between the topmost wafer and the lowermost wafer of the semiconductor wafers W loaded in the vertical furnace 1.

First and second groups of gas supply conduits 11p-21p are installed outside of the vertical furnace 1. In this embodiment, the first group of gas supply conduits include first to third gas supply conduits 11p, 13p, and 15p connected to the first to third gas nozzles 11n, 13n, and 15n, respectively, and the second group of gas supply conduits include fourth to sixth gas supply conduits 17p, 19p, and 21p connected to the fourth to sixth gas nozzles 17n, 19n, and 21n, respectively. The first to sixth gas supply conduits 11p, 13p, 15p, 17p, 19p, and 21p may penetrate the flange 3 to extend to the region under the vertical furnace 1.

A carrier gas 23 may be injected into the vertical furnace 1 through at least one gas supply conduit of the first to third gas supply conduits 11p, 13p, and 15p. The carrier gas 23 may include at least one of a hydrogen gas, a helium gas, a nitrogen gas, and an argon gas. In addition, the at least one carrier gas may be used to purge a process gas remaining in the vertical furnace 1. That is, the carrier gases may be used as purge gases 23a and 23b.

As described above, when the carrier gas 23 includes at least one gas of a hydrogen gas, a helium gas, a nitrogen gas, and an argon gas, at least one of the first to third gas supply conduits 11p, 13p, and 15p may be connected to a carrier gas tank (not shown). The gas supply conduit(s) connected to the carrier gas tank may include a gas supply conduit connected to the topmost gas nozzle of the first to third gas nozzles 11n, 13n, and 15n. For example, when the carrier gas tank includes at least one of a hydrogen gas tank and a helium gas tank, the hydrogen gas tank and/or the helium gas tank may be connected to the first gas supply conduit 11p. On the other hand, each of the hydrogen gas tank and the helium gas tank may be connected to the first group of gas supply conduits, i.e., the first to third gas supply conduits 11p, 13p, and 15p.

Furthermore, when the carrier gas tank includes at least one of a nitrogen gas tank and an argon gas tank, the nitrogen gas tank or the argon gas tank may be connected to the first to third gas supply conduits 11p, 13p, and 15p. In addition, when the carrier gas tank includes both the nitrogen gas tank and the argon gas tank, each of the nitrogen gas tank and the argon gas tank may be connected to the first to third gas supply conduits 11p, 13p, and 15p.

As described above, when the carrier gas has a relatively light atomic weight or a light molecular weight, such as when the carrier gas includes hydrogen gas and/or helium gas, the carrier gas may be supplied through only the first gas supply conduit 11p connected to the topmost nozzle (i.e., the first gas nozzle 11n). This is because the carrier gas can be uniformly supplied into the vertical furnace 1 through only the topmost nozzle when the carrier gas has a relatively light atomic weight. However, when the carrier gas has a relatively heavy atomic weight or heavy molecular weight, such as when the carrier gas includes nitrogen gas and/or argon gas, it is preferable that the carrier gas is supplied through the first to third gas supply conduits 11p, 13p, and 15p connected to the first to third gas nozzles 11n, 13n, and 15n.

A semiconductor source gas may be injected into the vertical furnace 1 through at least one of the first and second groups of gas supply conduits. The semiconductor source gas may include at least one of a silicon source gas 25a and a germanium source gas 25b. The silicon source gas 25a may include at least one of a monosilane (SiH₄) gas and a disilane (Si₂H₆) gas, and the germanium source gas may be a GeH₄ gas. The semiconductor source gas may be injected into the vertical furnace 1 together with the above-described carrier gas. In this case, the carrier gas functions to uniformly supply the semiconductor source gas throughout the entire space in the vertical furnace 1.

When the semiconductor source gas includes at least one of the monosilane (SiH₄) gas and the disilane (Si₂H₆) gas, the first to third gas supply conduits 11p, 13p, and 15p may be connected to a semiconductor source gas tank. That is, the first to third gas supply conduits 11p, 13p, and 15p may be connected to both a monosilane gas tank and a disilane gas tank. In another embodiment, when the semiconductor source gas includes the silicon source gas 25a and the germanium source gas 25b, the germanium source gas tank may be additionally connected to the fourth to sixth gas supply conduits 17p, 19p, and 21p. When the silicon source gas and the germanium source gas are simultaneously supplied into the vertical furnace 1, an epitaxial silicon germanium layer may be formed.

In addition, a selective etching gas may be injected into the vertical furnace 1 through at least one of the first and second groups of gas supply conduits. Preferably, the selective etching gas may contain halogen elements that react with silicon atoms and/or germanium atoms. For example, the selective etching gas may include a chlorine-based gas 27a such as a chlorine gas (Cl₂) or a hydrogen chloride (HCl) gas. However, the hydrogen chloride gas may not decompose into chlorine atoms and hydrogen atoms at temperatures lower than about 700° C. Therefore, in order to use the hydrogen chloride gas as the selective etching gas at a temperature lower than about 700° C., a catalyst gas 27b, such as GeH₄ gas 27b may be additionally injected. The selective etching gas may be injected into the vertical furnace 1 together with the above-described carrier gas. In this case, the carrier gas functions to uniformly supply the selective etching gas throughout the entire space in the vertical furnace 1.

When the selective etching gas is a chlorine gas, a chlorine gas tank may be connected to the fourth to sixth gas supply conduits 17p, 19p, and 21p. In another embodiment, when the selective etching gas is a hydrogen chloride gas, a hydrogen chloride gas tank may be connected to the fourth to sixth gas supply conduits 17p, 19p, and 21p, and a catalyst gas tank, i.e., a GeH₄ gas tank may be connected to the first to third gas supply conduits 11p, 13p, and 15p to accelerate thermal decomposition of the hydrogen chloride gas.

Furthermore, a dopant gas may be injected into the vertical furnace 1 through at least one of the first and second groups of gas supply conduits. For example, the dopant gas 29 may be injected through the fourth to sixth gas supply conduits 17p, 19p, and 21p. The dopant gas 29 is injected together with the semiconductor source gas to form an in situ doped epitaxial semiconductor layer. The dopant gas 29 may be one of a BC₁₃ gas and a PH₃ gas. The dopant gas 29 may be supplied from a BC₁₃ gas tank or a PH₃ gas tank connected to the fourth to sixth gas supply conduits 17p, 19p, and 21p.

Each of the process gases, the carrier gases, and the purge gases provided from all of the above-described gas tanks may be supplied through a single mass flow controller (MFC) or three mass flow controllers (MFCs) at a uniform flow rate. In particular, when each of the gas tanks is connected to the first to third gas supply conduits 11n, 13n, and 15n or the fourth to sixth gas supply conduits 17n, 19n, and 21n through 3 branched conduits, the mass flow controllers (MFCs) may be installed at the branched conduits, respectively.

The air and/or the process gases (or byproduct) in the vertical furnace 1 are vented through an exhaust line EL branched from a portion of the flange 3. The exhaust line EL is connected to an exhaust pump, and the exhaust pump may include a turbo molecular pump TMP and a dry pump DP for ultra high vacuum.

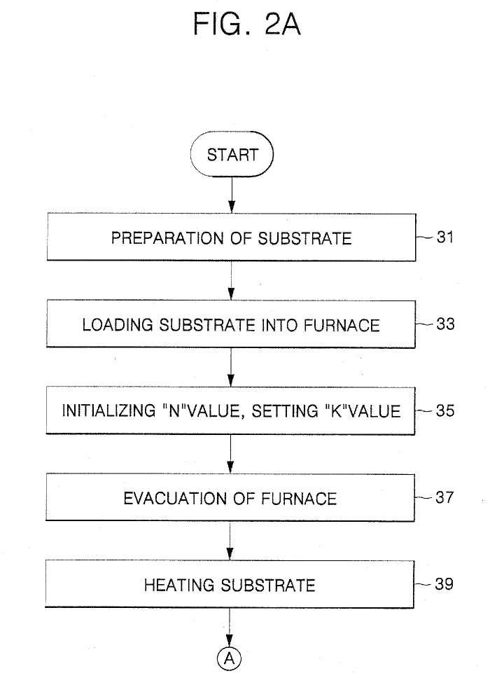

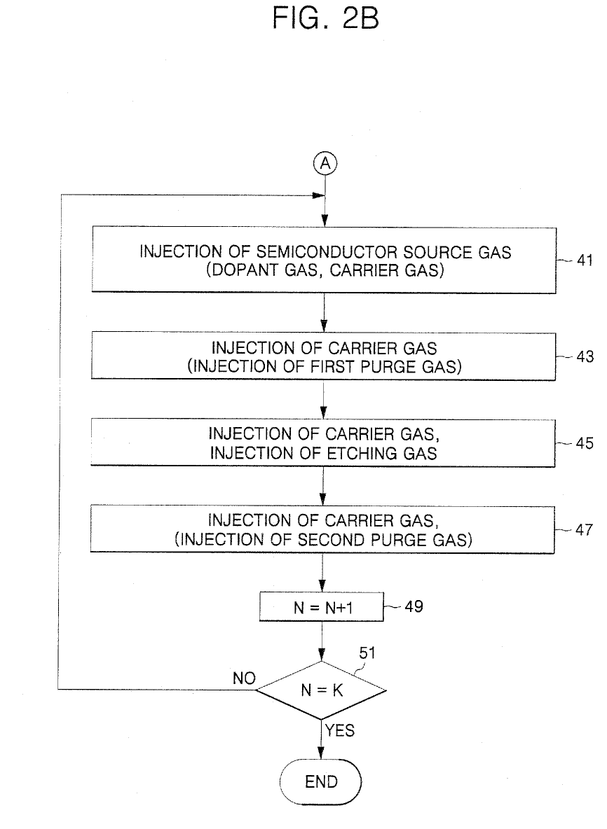

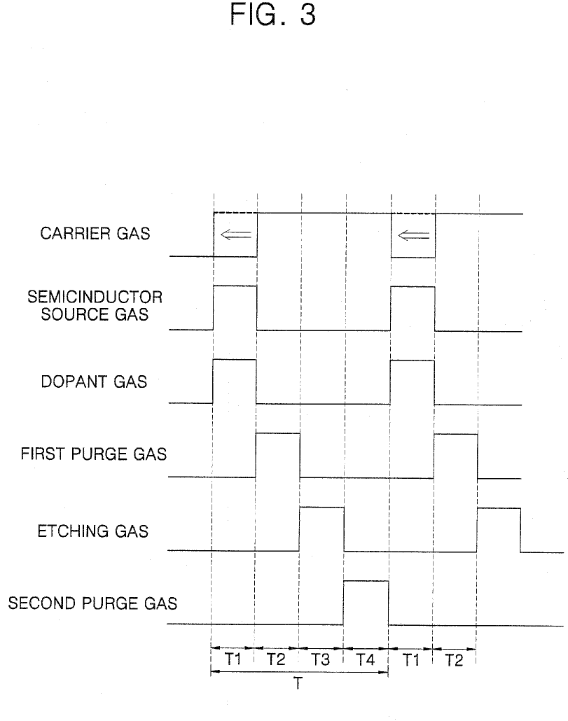

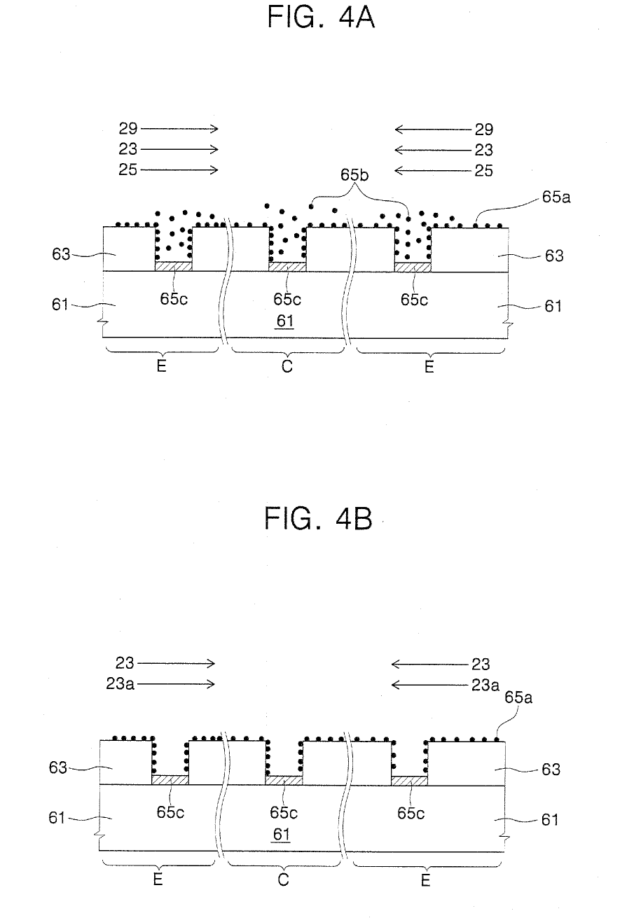

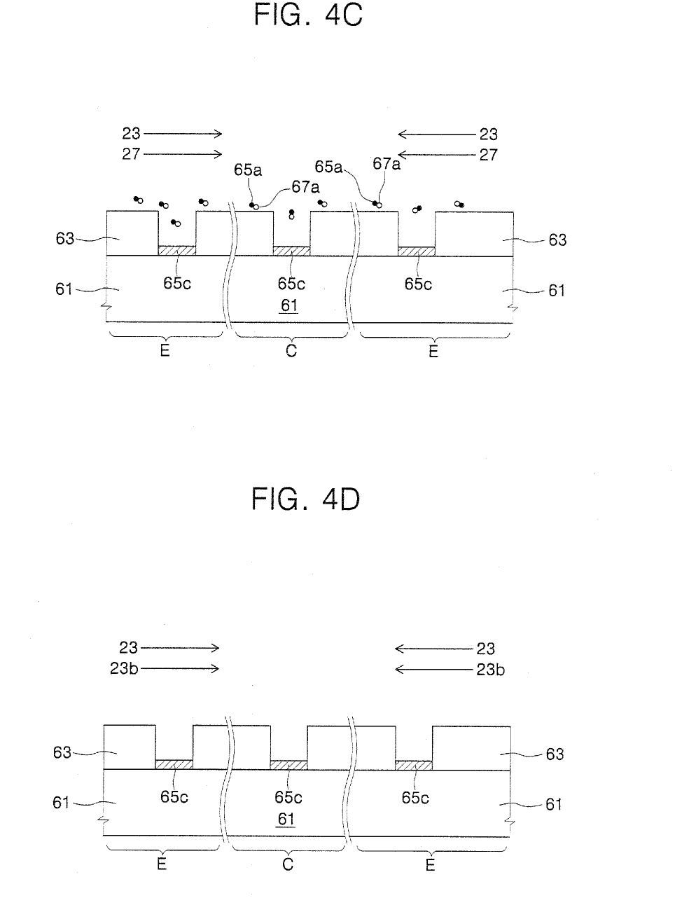

FIGS. 2A and 2B are process flowcharts illustrating a method of forming a selective epitaxial semiconductor layer using the apparatus illustrated in FIG. 1. FIG. 3 is a timing diagram illustrating an SEG process in accordance with an embodiment of the present invention. In addition, FIGS. 4A to 4D are cross-sectional views illustrating reaction mechanisms during an SEG process in accordance with an embodiment of the present invention. In FIGS. 4A to 4D, a reference character “C” indicates a central region of a semiconductor wafer, and a reference character “E” indicates an edge region of the semiconductor wafer.

Referring to FIGS. 1, 2A, 2B, 3, and 4A, a plurality of substrates W are provided (step 31 of FIG. 2A). Depending on application, a single substrate may be provided. The substrates W may be manufactured by forming an insulating layer 63 on each of the semiconductor substrates 61, such as semiconductor wafers and patterning the insulating layer 63 to form openings that expose predetermined regions of the respective semiconductor substrates 61.

The substrates W having the openings are loaded into the vertical furnace 1 (see FIG. 1) using the boat 5 (see FIG. 1) (step 33 of FIG. 2A). As a result, a space in the vertical furnace 1 is isolated from the external air. An N value allocated to a first register of a controller of the apparatus shown in FIG. 1 is initialized to “0”, and a K value allocated to a second register is set to a desired cycle number (step 35 of FIG. 2A).

The air in the vertical furnace 1 is then evacuated using the exhaust pump (TMP and DP in FIG. 1) to adjust an internal pressure of the vertical furnace 1 to a low base pressure of about 1×10⁻⁸ Torr to about 1×10⁻⁵ Torr (step 37 of FIG. 2A). The substrates W in the vertical furnace 1 are then heated to a predetermined process temperature, for example, about 550 to about 700° C. (step 39 of FIG. 2A). In another embodiment, the substrates W may be heated substantially simultaneously during the evacuation of the vertical furnace 1.

At least one semiconductor source gas 25 is injected into the vertical furnace 1 for a first duration T1 (step 41 of FIG. 2B). The first duration T1 may be about 10 to about 120 seconds. The semiconductor source gas 25 may include at least one of a silicon source gas 25a and a germanium source gas 25b. The silicon source gas 25a may include at least one of a monosilane (SiH₄) gas and a disilane (Si₂H₆) gas, and the germanium source gas 25b may include a GeH₄ gas. When the semiconductor source gas 25 is the silicon source gas 25a, such as a monosilane (SiH₄) gas and/or a disilane (Si₂H₆) gas as shown in FIG. 1, the silicon source gas can be uniformly supplied throughout the space in the vertical furnace 1 through the first group of gas nozzles, i.e., the first to third gas nozzles 11n, 13n, and 15n (see FIG. 1). Alternatively, when the semiconductor source gas 25 includes the silicon source gas 25a and the germanium source gas 25b, the silicon source gas 25a and the germanium source gas 25b can be uniformly supplied throughout the entire space in the vertical furnace 1 through the first to third gas nozzles 11n, 13n, and 15n and the fourth to sixth gas nozzles 17n, 19n, and 21n, respectively, as shown in FIG. 1.

As mentioned above, this embodiment only shows three nozzles in the first group of gas nozzles and three nozzles in the second group of gas nozzles for the sake of clarity of explanation and convenience. However, in other embodiments of the present invention, the number of nozzles in the first group of gas nozzles may vary from three, and be, for example, one, two, or at least four. Similarly, the number of gas nozzles in the second group of gas nozzles may vary from the three shown in the present invention (such as one, two, or at least four). Further the term “batch size” means the maximum number of substrates W that can be loaded into the vertical furnace 1.

Referring back to FIGS. 1-4, if the semiconductor source gas 25 is injected into the vertical furnace 1, the semiconductor source gas 25 is decomposed by thermal energy in the vertical furnace 1 to generate semiconductor atoms. For example, when a monosilane gas is injected into the vertical furnace 1, the monosilane gas is decomposed into silicon atoms and hydrogen atoms. The semiconductor atoms decomposed from the semiconductor source gas may bond to dangling bonds at the surfaces of the exposed portions of the semiconductor substrates 61 and the insulating layer 63. That is, the semiconductor atoms may be adsorbed at attached to the surfaces of the exposed semiconductor substrates 61 and the insulating layer 63. In general, the bonding energy of the semiconductor atoms adsorbed on an insulating layer 63 is smaller than that of the semiconductor atoms adsorbed on the semiconductor substrate layers 61, and an incubation time of the semiconductor atoms on the insulating layer 63 may be longer than that of the semiconductor atoms on the semiconductor substrate layer 61. Therefore, when the semiconductor source gas is injected for the first duration T1, first semiconductor atoms 65a may be adsorbed on a surface of the insulating layer 63 to form semiconductor seeds or a semiconductor seed layer, and epitaxial semiconductor layers 65c may be formed to a small thickness of several angstroms (Å) to several tens of angstroms (Å) on the exposed semiconductor substrates 61. In addition, unreacted semiconductor atoms, i.e., second semiconductor atoms 65b may exist over the surfaces of the insulating layers 63 in the vertical furnace 1.

If the semiconductor source gas 25 is a monosilane gas, the total flow rate of the monosilane gas injected through the first to third gas nozzles 11n, 13n, and 15n may be about 50 sccm to about 600 sccm. In addition, when the semiconductor source gas 25 is a disilane gas, the total flow rate of the disilane gas injected through the first to third gas nozzles 11n, 13n, and 15n may also be about 50 sccm to about 600 sccm. Alternatively, when the semiconductor source gas 25 includes a monosilane gas and a disilane gas, the total flow rate of the monosilane gas and the disilane gas injected through the first to third gas nozzles 11n, 13n, and 15n may be about 50 sccm to about 1000 sccm.

In another embodiment, the semiconductor source gas 25 may include a monosilane gas and a GeH₄ gas. In this case, the monosilane gas and the GeH₄ gas can be injected through the first to third gas nozzles 11n, 13n, and 15n and the fourth to sixth gas nozzles 17n, 19n, and 21n, respectively, and the total flow rate of the monosilane gas and the GeH₄ gas injected through the first to sixth gas nozzles 11n, 13n, 15n, 17n, 19n, and 21n may be about 50 sccm to about 1500 sccm.

In still another embodiment, the semiconductor source gas 25 may include a disilane gas and a GeH₄ gas. In this case, the disilane gas and the GeH₄ gas can be injected through the first to third gas nozzles 11n, 13n, and 15n and the fourth to sixth gas nozzles 17n, 19n, and 21n, respectively, and the total flow rate of the disilane gas and the GeH₄ gas injected through the first to sixth gas nozzles 11n, 13n, 15n, 17n, 19n, and 21n may be about 50 sccm to about 1500 sccm.

In yet another embodiment, the semiconductor source gas 25 may include a monosilane gas, a disilane gas, and a GeH4 gas. In this case, the mono-silane gas and the di-silane gas can be injected through the first to third gas nozzles 11n, 13n, and 15n, and the GeH₄ gas can be injected through the fourth to sixth gas nozzles 17n, 19n, and 21n. The total flow rate of the monosilane gas, the disilane gas, and the GeH₄ gas injected through the first to sixth gas nozzles 11n, 13n, 15n, 17n, 19n, and 21n may be about 50 sccm to about 1500 sccm.

Furthermore, the semiconductor source gas 25 may be injected together with a carrier gas 23 for the first duration T1. As described with reference to FIG. 1, the carrier gas 23 may include at least one gas selected from a hydrogen gas, a helium gas, a nitrogen gas, and an argon gas. In this case, the carrier gas 23 is injected in order to uniformly supply the semiconductor source gas 25 on the surfaces of the substrates W in the vertical furnace 1. However, when the semiconductor source gas 25 is injected together with the carrier gas 23, for example, s hydrogen gas, hydrogen atoms decomposed from the hydrogen gas may bond to dangling bonds at the surfaces of the exposed semiconductor substrates 61 or surfaces of the epitaxial semiconductor layers 65c, thereby degrading the growth rate or growth rate uniformity of the epitaxial semiconductor layers 65c during the first duration T1. Therefore, if the semiconductor source gas 25 can sufficiently lower the process pressure in the vertical furnace 1 for the first duration T1 so that semiconductor atoms decomposed from the semiconductor source gas 25 have a mean free path of several tens of mm or more without the aid of the carrier gas 23, it is preferable that the semiconductor source gas 25 is injected without the carrier gas 23.

In yet still another embodiment, the semiconductor source gas 25 may be injected together with a dopant gas 29. The dopant gas 29 may be a boron chloride (BC₁₃) gas, a phosphine (PH₃) gas, a diborane (B₂H₆) gas, or an arsine (AsH₃) gas. When the semiconductor source gas 25 is injected together with the dopant gas 29, the epitaxial semiconductor layers 65c correspond to in situ doped epitaxial semiconductor layers.

In addition, the semiconductor source gas 25 may be injected together with the dopant gas 29 and the carrier gas 23.

The internal pressure of the vertical furnace 1 may be maintained at a process pressure of about 1×10⁻³ Torr to about 1×10⁻¹ Torr for the first duration T1 during which at least the semiconductor source gas 25 is injected.

Referring to FIGS. 1, 2A, 2B, 3, and 4B, after injection of the semiconductor source gas 25 for the first duration T1, the carrier gas 23 may be injected into the vertical furnace 1 for a second duration T2 to purge the semiconductor source gas 25 and the second semiconductor atoms 65b which remain in the vertical furnace 1 (Step 43 of FIG. 2B). When the semiconductor source gas 25 is injected together with the dopant gas 29 for the first duration T1, the dopant gas 29 remaining in the vertical furnace 1 may also be purged during the second duration T2. The second duration T2 may be about 10 seconds to about 120 seconds, and the flow rate of the carrier gas 23 injected for the second duration T2 may be about 500 sccm to about 1000 sccm.

In another embodiment, a first purge gas 23a may be additionally injected for the second duration T2. The first purge gas 23a may be a hydrogen gas, a helium gas, a nitrogen gas, or an argon gas. In this case, the first purge gas 23a may be different from the carrier gas 23, and the total flow rate of the carrier gas 23 and the first purge gas 23a may be about 500 sccm to about 1000 sccm.

After the injection of at least the carrier gas 23 for the second duration T2, the process gases in the vertical furnace 1 may be entirely removed.

The internal pressure of the vertical furnace 1 may be maintained at a process pressure of about 1×10⁻³ Torr to about 1×10⁻¹ Torr during the second duration T2 in which at least the carrier gas 23 is injected.

Referring to FIGS. 1, 2A, 2B, 3, and 4C, after injection of at least the carrier gas 23 for the second duration T2, a selective etching gas 27 is injected together with the carrier gas 23 into the vertical furnace 1 for a third duration T3 (step 45 of FIG. 2B). The third duration T3 may be about 10 seconds to about 180 seconds, and the selective etching gas 27 may be a gas including halogen elements which react with the first semiconductor atoms 65a adsorbed on the insulating layer 63. For example, the selective etching gas 27 may be a chlorine-based gas 27a such as a chlorine gas (Cl₂) or a hydrogen chloride (HCl) gas. When the hydrogen chloride gas is used as the selective etching gas 27, a catalyst gas such as GeH₄ gas may be additionally injected as described with reference to FIG. 1. The carrier gas 23 increases the mean free path of the selective etching gas 27 to uniformly supply the selective etching gas 27 to surfaces of the substrates W in the vertical furnace 1.

When the selective etching gas 27 is injected into the vertical furnace 1, the selective etching gas 27 is decomposed by thermal energy in the vertical furnace 1 to generate chlorine atoms 67a. The chlorine atoms 67a decomposed from the selective etching gas 27 may be bonded to the first semiconductor atoms 65a adsorbed on surfaces of the insulating layers 63 to detach the first semiconductor atoms 65a from the surfaces of the insulating layers 63. For example, when the first semiconductor atoms 65a are silicon atoms, the chlorine atoms 67a react with the silicon atoms to produce volatile by-products such as SiC₁₄ or SiC₁₃.

The flow rate of the selective etching gas 27 injected for the third duration T3 may be about 50 sccm to about 1500 sccm. For example, when the selective etching gas 27 is a chlorine gas, the flow rate of the chlorine gas may be about 50 sccm to about 400 sccm. In addition, when the selective etching gas 27 such as a hydrogen chloride gas and the catalyst gas such as a GeH₄ gas are injected for the third duration (T3), the total flow rate of the chloride gas and the GeH₄ gas may be about 100 sccm to about 1500 sccm. An internal pressure of the vertical furnace 1 may be maintained at a process pressure of about 1×10⁻³ Torr to about 1×10⁻¹ Torr during the third duration T3.

Referring to FIGS. 1, 2A, 2B, 3, and 4D, after injection of the selective etching gas 27 and the carrier gas 23 for the third duration T3, the carrier gas 23 may be injected into the vertical furnace 1 for a fourth duration T4 to purge the selective etching gas 27 and the reaction by-products which remain in the vertical furnace 1 (step 47 of FIG. 2B). The fourth duration T4 may be about 10 seconds to about 360 seconds, and the flow rate of the carrier gas 23 injected for the fourth duration T4 may be about 500 sccm to about 1000 sccm.

In another embodiment, a second purge gas 23b may be additionally injected for the fourth duration T4. The second purge gas 23b may be a hydrogen gas, a helium gas, a nitrogen gas, or an argon gas. In this case, the second purge gas 23b may be different from the carrier gas 23, and the total flow rate of the carrier gas 23 and the second purge gas 23b may be about 500 sccm to about 1000 sccm.

An internal pressure of the vertical furnace 1 may be maintained at a process pressure of about 1×10⁻³ Torr to about 1×10⁻¹ Torr during the fourth duration T4 that at least the carrier gas 23 is injected.

After the injection of at least the carrier gas 23 for the fourth duration T4, the process gases in the vertical furnace 1 are entirely removed and the first semiconductor atoms 65a adsorbed on the surfaces of the insulating layers 63 can also be removed. In addition, the carrier gas 23 may be injected for at least the second to fourth durations T2, T3, and T4 to uniformly supply at least the selective etching gas 27 onto the surfaces of the substrates W loaded into the vertical furnace 1. Therefore, during a single cycle time T, corresponding to the sum of the first to fourth durations T1, T2, T3, and T4, the epitaxial semiconductor layers 65c may be selectively formed only on the exposed semiconductor substrates 61 to a uniform thickness.

After injection of at least the carrier gas 23 for the fourth duration T4, the “N” value is increased by 1 (step 49 of FIG. 2B). The increased “N” value is compared with the “K” value (step 51 of FIG. 2B). The injection process 41 of the semiconductor source gas 25, the first purge process 43, the injection process 45 of the selective etching gas 27, and the second purge process 47 may be sequentially repeated until the “N” value is equal to the “K” value, at which time the epitaxial semiconductor layers may be formed to have a desired thickness on the exposed semiconductor layers 61.

### EXAMPLES

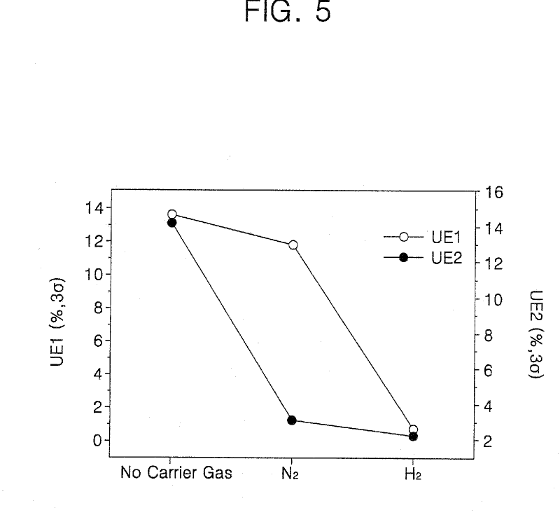

FIG. 5 is a graph showing the relationship between the etch uniformity and the carrier gas of SEG processes in accordance with embodiments of the present invention. In FIG. 5, the abscissa represents split conditions of the carrier gas, the left ordinate represents first etch uniformity UE1 corresponding to wafer etch uniformity, and the right ordinate represents second etch uniformity UE2 corresponding to etch uniformity within the wafer. After repeatedly applying only the selective etching process (step 45 of FIG. 2A) to semiconductor wafers having polysilicon layers for a certain period, the etch uniformities UE1 and UE2 were calculated from variations in the thickness of the polysilicon layers. The selective etching process was performed using main process conditions described in the following table [Table 1]. In the present experiment, a selective etching gas was injected through three gas nozzles as described with reference to FIG. 1.

TABLE 1

| Process parameters | Process conditions | | |
|---|---|---|---|
| Number of loaded wafers | 100 sheets | | |
| Carrier gas nozzle | Single nozzle (installed at upper | | |
| | portion in vertical furnace) | | |
| Process pressure | 1 × 10⁻¹ Torr | | |
| Wafer temperature | 620° C. | | |
| Selective etching gas | Chlorine gas (Cl₂), 70 sccm | | |
| Carrier gas injected together | None | Nitrogen gas | Hydrogen gas |
| with selective etching gas | | (N₂), | (H₂), |
| | | 1000 sccm | 1000 sccm |

As can be seen from FIG. 5 and [Table 1], when a selective etching process was performed using only chlorine gas without a carrier gas, first and second etch uniformities UE1 and UE2 were about 13% and 14%, respectively. In addition, when the selective etching process was performed using a nitrogen gas as a carrier gas of the chlorine gas, the first and second etch uniformities UE1 and UE2 were about 12% and 3%, respectively. Further, when the selective etching process was performed using a hydrogen gas as a carrier gas of the chlorine gas, the first and second etch uniformities UE1 and UE2 were about 1% and 2%, respectively.

Therefore, it can be appreciated that a selective etching gas such as a chlorine gas is preferably injected into the vertical furnace with a carrier gas. In particular, when the carrier gas is injected through a single nozzle as described in [Table 1], it will be appreciated that a hydrogen gas may be more suitable than a nitrogen gas for a carrier gas because of the improved etch uniformity between wafers (i.e., the first etch uniformity UE1).

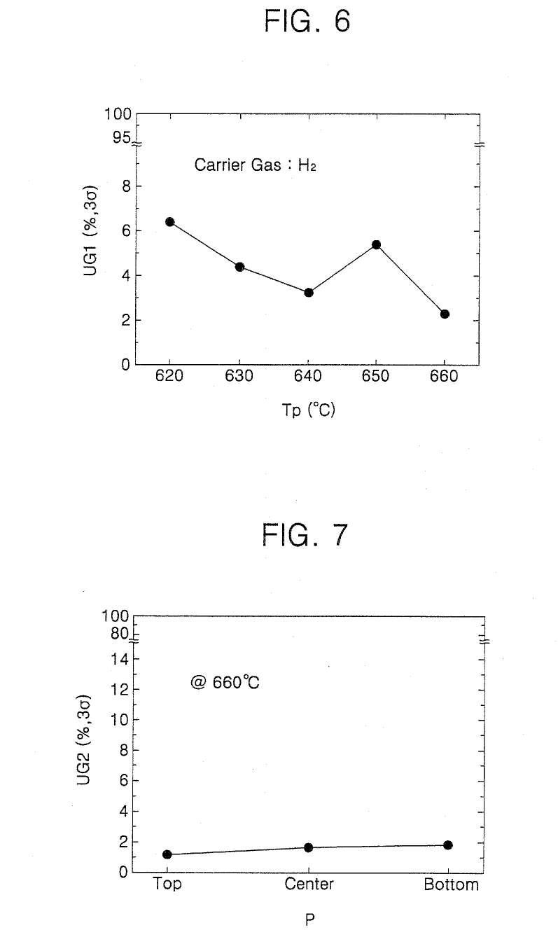

FIG. 6 is a graph showing the relationship between wafer to wafer growth uniformity and process temperature of epitaxial silicon layers manufactured in accordance with embodiments of the present invention. FIG. 7 is a graph showing the relationship between growth uniformity within a wafer and the position of the wafers having epitaxial silicon layers manufactured in accordance with embodiments of the present invention. In FIG. 6, the abscissa represents a process temperature Tp, and the ordinate represents a first growth uniformity UG1 corresponding to wafer growth uniformity. In FIG. 7, the abscissa represents a wafer position P, and the ordinate represents a second growth uniformity UG2 corresponding to a growth uniformity within the wafer.

Samples exhibiting experimental results of FIGS. 6 and 7 were manufactured using main process conditions described in the following table [Table 2]. A hydrogen gas was used as a carrier gas, and the hydrogen gas was injected during all of the processes (i.e., first to fourth durations T1, T2, T3, and T4) at a flow rate of about 1000 sccm. In this experiment, a semiconductor source gas was injected through the first group of gas nozzles 11n, 13n, and 15n as shown FIG. 1, and a selective etching gas was injected through the second group of gas nozzles 17n, 19n, and 21n as shown in FIG. 1.

TABLE 2

| Process parameters | Process conditions |
|---|---|
| Number of loaded wafers | 100 sheets |
| Carrier gas nozzle | Single nozzle (installed at upper portion in |
| | vertical furnace) |
| Carrier gas | Hydrogen gas (H₂) |
| Base pressure | 1 × 10⁻⁶ Torr |
| Process pressure | 1 × 10⁻¹ Torr |
| First duration T1 | 100 seconds |
| Semiconductor source gas | Monosilane gas (SiH₄), 100 sccm |
| Second duration T2 | 120 seconds |
| Third duration T3 | 60 seconds |
| Selective etching gas | Chlorine gas (Cl₂), 70 sccm |
| Fourth duration T4 | 180 seconds |

As can be seen from FIG. 6 and [Table 2], epitaxial silicon layers formed according to embodiments of the present invention exhibited the first growth uniformity UG1 of about 2% to 6.5% throughout all of the wafers at a process temperature Tp of about 620 to about 660° C.

In addition, as can be seen from FIG. 7 and [Table 2], that epitaxial silicon layers formed on a topmost wafer (top of FIG. 7), a center wafer (center of FIG. 7) and a lowermost wafer (bottom of FIG. 7) among 100 wafers loaded into the vertical furnace exhibited similar second growth uniformities (UG2) of about 1%, 2%, and 2%, respectively.

According to the present invention as described above, it is possible to grow uniform epitaxial semiconductor layers using a batch-type ultra-high vacuum chemical vapor deposition apparatus at a temperature lower than about 700° C. Therefore, although a selective epitaxial process in accordance with the present invention is employed in fabrication of a semiconductor device, it can prevent characteristics of MOS transistors from being degraded without reduction of throughput. In addition, the selective epitaxial process in accordance with the present invention is performed using an ultra-high vacuum chemical vapor deposition apparatus having a plurality of gas nozzles. Therefore, it is possible to improve the uniformity of the epitaxial semiconductor layers formed on the plurality of wafers.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor manufacturing process, comprising:
a) forming an insulating layer pattern on a semiconductor substrate to expose at least one region of the semiconductor substrate;
b) loading the substrate having the insulating layer pattern into a reaction chamber;
c) evacuating the reaction chamber and heating the substrate in the reaction chamber to a temperature of about 550 to about 700° C.;
d) injecting a semiconductor source gas into the reaction chamber to selectively form an epitaxial semiconductor layer on the exposed region of the heated substrate;
e) purging the semiconductor source gas remaining in the reaction chamber;
f) injecting a selective etching gas into the reaction furnace where the semiconductor source gas is purged, thereby selectively removing semiconductor atoms adsorbed on surfaces of the insulating layer pattern; and
g) purging the selective etching gas remaining in the reaction chamber,
wherein at least the step f) among the steps d), e), f), and g) is performed along with injecting a carrier gas into the reaction chamber.

2. The semiconductor manufacturing process according to claim 1, wherein at least steps e), f), and g) among the steps d), e), f), and g) are performed along with injecting the carrier gas into the reaction chamber.

3. The semiconductor manufacturing process according to claim 1, wherein evacuating the reaction chamber and heating the substrate comprises:
removing air from the reaction chamber using an exhaust pump to lower the base pressure in the reaction chamber; and
heating the substrate in the reaction chamber to a temperature of about 550 to about 700° C. after removing air from the reaction chamber.

4. The semiconductor manufacturing process according to claim 3, wherein removing the air from the reaction chamber and heating the substrate are performed substantially simultaneously.

5. The semiconductor manufacturing process according to claim 3, wherein loading the substrate in the reaction chamber comprises:
loading a plurality of substrates having an insulating layer pattern in a boat; and
loading the boat having the plurality of substrates in the reaction chamber so that the plurality of substrates enter the reaction chamber simultaneously.

6. The semiconductor manufacturing process according to claim 1, wherein the steps d), e), f), and g) are sequentially and repeatedly performed at least twice.

7. The semiconductor manufacturing process according to claim 1, wherein an internal pressure of the vertical chamber reaches a base pressure of about 1×10⁻⁸ Torr to about 1×10⁻⁵ Torr while the semiconductor substrate is heated.

8. The semiconductor manufacturing process according to claim 1, wherein the steps d), e), f), and g) are performed under a process pressure of about 1×10⁻³ Torr to about 1×10⁻¹ Torr.

9. The semiconductor manufacturing process according to claim 1, wherein the semiconductor source gas comprises at least one of a silicon source gas and a germanium source gas.

10. The semiconductor manufacturing process according to claim 9, wherein the silicon source gas includes at least one of a SiH₄ gas and a Si2H₆ gas, and the germanium source gas includes a GeH₄ gas.

11. The semiconductor manufacturing process according to claim 1, wherein the carrier gas includes at least one of a hydrogen gas, a helium gas, a nitrogen gas, and an argon gas.

12. The semiconductor manufacturing process according to claim 11, wherein the carrier gas is injected at a flow rate of about 500 sccm to about 1000 sccm.

13. The semiconductor manufacturing process according to claim 1, wherein the semiconductor source gas is injected together with the carrier gas.

14. The semiconductor manufacturing process according to claim 1, wherein the semiconductor source gas is injected together with a dopant gas.

15. The semiconductor manufacturing process according to claim 14, wherein the dopant gas includes at least one of a BC₁₃ gas, a B₂H₆ gas, an AsH₃ gas, and a PH₃ gas.

16. The semiconductor manufacturing process according to claim 1, wherein the semiconductor source gas is injected together with the carrier gas and a dopant gas.

17. The semiconductor manufacturing process according to claim 1, wherein the semiconductor source gas is injected for about 10 seconds to about 120 seconds.

18. The semiconductor manufacturing process according to claim 1, wherein purging the semiconductor source gas comprises injecting a first purge gas in addition to the carrier gas into the reaction chamber, and wherein purging the selective etching gas comprises injecting a second purge gas in addition to the carrier gas into the reaction chamber.

19. The semiconductor manufacturing process according to claim 18, wherein the first purge gas includes at least one of a hydrogen gas, a helium gas, a nitrogen gas, and an argon gas, and the second purge gas includes at least one of a hydrogen gas, a helium gas, a nitrogen gas, and an argon gas, the first and second purge gases being different from the carrier gas.

20. The semiconductor manufacturing process according to claim 19, wherein a total flow rate of the carrier gas and the first purge gas is about 500 sccm to about 1000 sccm, and a total flow rate of the carrier gas and the second purge gas is about 500 sccm to about 1000 sccm.

21. The semiconductor manufacturing process according to claim 1, wherein the semiconductor source gas is purged for about 10 seconds to about 120 seconds, and the selective etching gas is purged for about 10 seconds to about 360 seconds.

22. The semiconductor manufacturing process according to claim 1, wherein the selective etching gas includes a chlorine gas or includes a mixed gas of hydrogen chloride (HCl) and GeH₄.

23. The semiconductor manufacturing process according to claim 1, wherein the selective etching gas is injected for about 10 seconds to about 180 seconds.

24. An ultra-high vacuum chemical vapor deposition selective epitaxial growth (UHVCVD SEG) process, comprising:
a) forming insulating layer patterns on a plurality of semiconductor substrates to expose predetermined regions of the semiconductor substrates;
b) loading the substrates having the insulating layer patterns into a vertical furnace;
c) evacuating the vertical furnace through an exhaust line installed at a lower portion of the vertical furnace and heating the substrates in the vertical furnace to a temperature of about 550 to about 700° C.;
d) injecting a semiconductor source gas into the vertical furnace through a plurality of nozzles installed at different heights inside the vertical furnace to form an epitaxial semiconductor layer on the predetermined regions of the heated semiconductor substrates;
e) purging the semiconductor source gas remaining in the vertical furnace;
f) injecting a selective etching gas into the vertical furnace to selectively remove semiconductor atoms adsorbed on surfaces of the insulating layer patterns, the selective etching gas being injected through the plurality of nozzles; and
g) purging the selective etching gas remaining in the vertical furnace,
wherein at least the steps e), f), and g) among the steps d), e), f), and g) are performed concurrently with injecting a carrier gas into the vertical furnace through at least a topmost nozzle of the plurality of nozzles.

25. The UHVCVD SEG process according to claim 24, wherein the steps d), e), f), and g) are sequentially and repeatedly performed at least twice.

26. The UHVCVD SEG process according to claim 24, wherein an internal pressure of the vertical furnace reaches a base pressure of about 1×10⁻⁸ Torr to about 1×10⁻⁵ Torr while the semiconductor substrates are heated.

27. The UHVCVD SEG process according to claim 24, wherein the steps d), e), f), and g) are performed under a process pressure of about 1×10⁻³ Torr to about 1×10⁻¹ Torr.

28. The UHVCVD SEG process according to claim 24, wherein the plurality of nozzles comprise a first group of nozzles having different heights from each other and a second group of nozzles facing the first group of nozzles, the first and second groups of nozzles being disposed to have levels between a topmost substrate and a lowermost substrate of the plurality of substrates.

29. The UHVCVD SEG process according to claim 28, wherein the carrier gas is injected through at least a topmost nozzle of the first group of nozzles or at least a topmost nozzle of the second group of nozzles when the carrier gas is a hydrogen gas or a helium gas, the carrier gas having a total flow rate of about 500 sccm to about 1000 sccm.

30. The UHVCVD SEG process according to claim 28, wherein the carrier gas is injected through the first group of nozzles or the second group of nozzles when the carrier gas is a nitrogen gas or an argon gas, the carrier gas having a total flow rate of about 500 sccm to about 1000 sccm.

31. The UHVCVD SEG process according to claim 28, wherein the semiconductor source gas is injected through the first group of nozzles or the second group of nozzles when the semiconductor source gas is a silicon source gas or a germanium source gas.

32. The UHVCVD SEG process according to claim 28, wherein the semiconductor source gas comprises a silicon source gas and a germanium source gas, the silicon source gas injected through the first group of nozzles and the germanium source gas injected through the second group of nozzles.

33. The UHVCVD SEG process according to claim 29, wherein the semiconductor source gas is injected together with the carrier gas.

34. The UHVCVD SEG process according to claim 33, wherein the carrier gas is injected through at least a topmost nozzle of the first group of nozzles or at least a topmost nozzle of the second group of nozzles when the carrier gas injected during the steps d), e), f), and g) is a hydrogen gas or a helium gas, the carrier gas having a total flow rate of about 500 sccm to about 1000 sccm.

35. The UHVCVD SEG process according to claim 33, wherein the carrier gas is injected through the first group of nozzles or the second group of nozzles when the carrier gas injected during steps d), e), f), and g) is a nitrogen gas or an argon gas, the carrier gas having a total flow rate of about 500 sccm to about 1000 sccm.

36. The UHVCVD SEG process according to claim 28, wherein the semiconductor source gas is injected together with a dopant gas.

37. The UHVCVD SEG process according to claim 36, wherein the dopant gas is injected through the first group of nozzles or the second group of nozzles.

38. The UHVCVD SEG process according to claim 28, wherein the semiconductor source gas is injected together with a dopant gas in addition to the carrier gas.

39. The UHVCVD SEG process according to claim 28, wherein purging the semiconductor source gas is performed by injecting a first purge gas in addition to the carrier gas into the vertical furnace, and wherein purging the selective etching gas is performed by injecting a second purge gas in addition to the carrier gas into the vertical furnace,
wherein a total flow rate of the carrier gas and the first purge gas is about 500 sccm to about 1000 sccm during the purging of the semiconductor source gas, and a total flow rate of the carrier gas and the second purge gas is about 500 sccm to about 1000 sccm during the purging of the selective etching gas.

40. The UHVCVD SEG process according to claim 39, wherein the carrier gas includes at least one of a hydrogen gas, a helium gas, a nitrogen gas, and an argon gas, and the first and second purge gases include at least one of a hydrogen gas, a helium gas, a nitrogen gas, and an argon gas, the first and second purge gases being different from the carrier gas.

41. The UHVCVD SEG process according to claim 39, wherein the first and second purge gases are injected through at least one nozzle of the first and second groups of nozzles.

42. The UHVCVD SEG process according to claim 28, wherein the selective etching gas is injected through the first group of nozzles or the second group of nozzles, when the selective etching gas is a single gas of chlorine gas.

43. The UHVCVD SEG process according to claim 28, wherein the selective etching gas comprises a hydrogen chloride (HCl) gas and a GeH₄ gas, the hydrogen chloride gas injected through the first group of nozzles and the GeH₄ gas injected through the second group of nozzles.

44. A batch-type ultra-high vacuum chemical vapor deposition selective epitaxial growth (UHVCVD SEG) apparatus, comprising:
a vertical furnace;
a first group of nozzles installed in the vertical furnace to have different heights from each other;
a second group of nozzles installed in the vertical furnace to have different heights from each other, the second group of nozzles facing the first group of nozzles;
a flange attached to a lower portion of the vertical furnace;
a first group of gas supply conduits installed outside the vertical furnace and connected respectively to the first group of nozzles, the first group of gas supply conduits passing through the flange;
a second group of gas supply conduits installed outside the vertical furnace and connected respectively to the second group of nozzles, the second group of gas supply conduits passing through the flange;
a carrier gas tank connected to at least one of the first group of gas supply conduits, wherein the at least one of the first group of gas supply conduits includes a gas supply conduit connected to a topmost nozzle of the first group of nozzles;
a source gas tank connected to at least one group of the first and second groups of gas supply conduits; and
a selective etching gas tank connected to at least one group of the first and second groups of gas supply conduits.

45. The batch-type UHVCVD SEG apparatus according to claim 44, further comprising:
an exhaust line passing through the flange; and
an exhaust pump connected to the exhaust line outside the vertical furnace to evacuate the vertical furnace.

46. The batch-type UHVCVD SEG apparatus according to claim 44, wherein the exhaust pump comprises a main pump connected to the exhaust line and an auxiliary pump connected to the main pump.

47. The batch-type UHVCVD SEG apparatus according to claim 44, wherein the main pump is a turbo molecular pump and the auxiliary pump is a dry pump.

48. The batch-type UHVCVD SEG apparatus according to claim 44, wherein the carrier gas tank comprises at least one of a hydrogen gas tank, a helium gas tank, a nitrogen gas tank, and an argon gas tank.

49. The batch-type UHVCVD SEG apparatus according to claim 48, wherein the hydrogen gas tank and/or the helium gas tank are connected to a gas supply conduit connected to the topmost nozzle of the first group of nozzles.

50. The batch-type UHVCVD SEG apparatus according to claim 48, wherein the hydrogen gas tank and/or the helium gas tank are connected to the first group of gas supply conduits.

51. The batch-type UHVCVD SEG apparatus according to claim 48, wherein the nitrogen gas tank and/or the argon gas tank are connected to the first group of gas supply conduits.

52. The batch-type UHVCVD SEG apparatus according to claim 44, wherein the source gas tank comprises at least one of a silicon source gas tank and a germanium source gas tank.

53. The batch-type UHVCVD SEG apparatus according to claim 52, wherein the silicon source gas tank is connected to the first group of gas supply conduits, and the germanium source gas tank is connected to the second group of gas supply conduits.

54. The batch-type UHVCVD SEG apparatus according to claim 44, wherein the selective etching gas tank is a chlorine gas tank.

55. The batch-type UHVCVD SEG apparatus according to claim 54, wherein the chlorine gas tank is connected to the second group of gas supply conduits.

56. The batch-type UHVCVD SEG apparatus according to claim 44, wherein the selective etching gas tank comprises a hydrogen chloride (HCl) gas tank and a GeH₄ gas tank.

57. The batch-type UHVCVD SEG apparatus according to claim 56, wherein the GeH₄ gas tank is connected to the first group of gas supply conduits, and the hydrogen chloride (HCl) gas tank is connected to the second group of gas supply conduits.

58. The batch-type UHVCVD SEG apparatus according to claim 44, further comprising a dopant gas tank connected to the first group of gas supply conduits or the second group of gas supply conduits.

59. The batch-type UHVCVD SEG apparatus according to claim 58, wherein the dopant gas tank comprises at least one of a BC₁₃ gas tank and a PH₃ gas tank.
